(19) United States
(12) Patent Application Publication
(10) Pub. No.: US 2026/0288270 A1
(43) Pub. Date: Sep. 24, 2026

(54) TOUCH DISPLAY SUBSTRATE AND TOUCH DISPLAY APPARATUS

(71) Applicants: Chongqing BOE Optoelectronics Technology Co., Ltd., Chongqing (CN); BOE Technology Group Co., Ltd., Beijing (CN)

(72) Inventors: Zhongshan WU, Beijing (CN); Xiaoyuan WANG, Beijing (CN); Xiaofeng YIN, Beijing (CN); Junming CHEN, Beijing (CN); Bin WAN, Beijing (CN); Guodong YANG, Beijing (CN)

(21) Appl. No.: 18/868,812

(22) PCT Filed: Sep. 18, 2023
(86) PCT No.: PCT/CN2023/119432

§ 371 Date: Nov. 25, 2024

(51) Int. Cl. G06F 3/041; H10D 86/40

(52) U.S. Cl. CPC G06F 3/0412; H10D 86/441

(57) ABSTRACT

A touch display substrate and a touch display apparatus belong to the field of display technology. The touch display substrate includes: a substrate, gate lines and data lines, and sub-pixels. Each data line includes: main data lines and auxiliary data lines, any two adjacent main data lines are connected by one auxiliary data line, and any two main data lines adjacent to each other in the first direction are separated from each other by two sub-pixels. The adjacent main data lines are located on different straight lines, and the main data lines separated from each other are located on the same straight line; and each auxiliary data line spans at least two adjacent sub-pixels. The touch display substrate further includes: touch lines, each touch line includes: main touch lines and auxiliary touch lines, the main touch and the main data lines extending along the first direction are alternately arranged.

### TECHNICAL FIELD

The present disclosure relates to the field of display technology, and in particular to a touch display substrate and a touch display apparatus.

### BACKGROUND

With the continuous development of display technologies, a touch display product integrated with a touch function is increasingly popular with customers, and has a more and more extensive application. An On-Cell/In-Cell touch display product has the unique advantages of being light and thin, a simple manufacturing process, a good touch effect and the like. Especially for the In-Cell touch display product, a liquid crystal display panel may be thinned on opposite sides, so that the In-Cell touch display product has a simple lamination structure, a low cost, and becomes the focus of the current development.

### SUMMARY

The present disclosure is directed to at least one of the technical problems in the prior art, and provides a touch display substrate and a touch display apparatus.

In a first aspect, an embodiment of the present disclosure provides a touch display substrate, including: a substrate, gate lines and data lines on the substrate, and a plurality of sub-pixels in regions where the gate lines and the data lines cross each other; wherein two of the gate lines are arranged between every two adjacent rows of sub-pixels, the gate lines extend in a first direction, and each of the data lines includes: main data lines and auxiliary data lines, the main data lines extend in a second direction, the auxiliary data lines extend in the first direction, any two adjacent main data lines of each of the data lines are connected by one auxiliary data line of the data line, and any two main data lines adjacent to each other in the first direction are separated from each other by two sub-pixels; the first direction intersects with the second direction; the adjacent main data lines of each data line are located on different straight lines, and the main data lines separated from each other are located on the same straight line; and each of the auxiliary data lines spans at least two adjacent sub-pixels in the first direction; the touch display substrate further includes: touch lines on the substrate, each of the touch lines includes: main touch lines and auxiliary touch lines, the main touch lines extend along the second direction, the auxiliary touch lines extend along the first direction, any two adjacent main touch lines of each of the touch lines are connected by one auxiliary touch line of the touch line, the adjacent main touch lines of each of the touch lines are located on different straight lines, and the main touch lines separated from each other are located on the same straight line; and the main touch lines and the main data lines extending along the first direction are alternately arranged, and each of the auxiliary touch lines and each of the auxiliary data lines span the same number of the sub-pixels in the first direction.

Optionally, the plurality of sub-pixels include: first sub-pixels, second sub-pixels and third sub-pixels; and for two adjacent gate lines on two opposite sides of each row of sub-pixels, one gate line is connected to all first sub-pixels and one half of third sub-pixels in the row, and the other gate line is connected to all second sub-pixels and the other half of the third sub-pixels in the row.

Optionally, the gate lines are arranged on the substrate, and the data lines and the touch lines are arranged in the same layer and are on a side of the gate lines away from the substrate.

Optionally, an orthographic projection of the auxiliary data line extending along the second direction on the substrate and an orthographic projection of the auxiliary touch line extending along the second direction on the substrate are located on two opposite sides of an orthographic projection of a corresponding gate line on the substrate, respectively.

Optionally, the gate lines are on the substrate, the data lines are on a side of the gate lines away from the substrate, and the touch lines are on a side of the data lines away from the substrate.

Optionally, an orthographic projection of each of the auxiliary data lines on the substrate is between orthographic projections of two gate lines adjacent to the auxiliary data line on the substrate, and the orthographic projection of each of the auxiliary touch lines on the substrate overlaps with the orthographic projection of one corresponding gate line on the substrate.

Optionally, each sub-pixel includes: a thin film transistor, including: a gate electrode, a semiconductor layer and a drain electrode sequentially arranged along a direction away from the substrate, the gate electrode is connected to the corresponding gate line, and the drain electrode is connected to the corresponding data line; the drain electrode includes: a main portion and a first extension portion on a side of the main portion close to the corresponding gate line; and an orthographic projection of the main portion on the substrate covers a portion of an orthographic projection of the semiconductor layer on the substrate, and an orthographic projection of the first extension portion on the substrate does not overlap with the orthographic projection of the semiconductor layer on the substrate.

Optionally, each sub-pixel includes: a thin film transistor, including: a semiconductor layer, a gate electrode, and a drain electrode sequentially arranged along a direction away from the substrate, the gate electrode is connected to the corresponding gate line, and the drain electrode is connected to the corresponding data line.

Optionally, the drain electrode further includes: a second extension portion on a side of the main portion away from the corresponding gate line; and an orthographic projection of the second extension portion on the substrate does not overlap with an orthographic projection of the semiconductor layer on the substrate.

Optionally, the drain electrode further includes: a recessed portion on a side of the main portion close to the corresponding data line; and an orthographic projection of the recessed portion on the substrate falls within an orthographic projection of the gate electrode on the substrate.

Optionally, each sub-pixel further includes: a pixel electrode on a side of the drain electrode away from the substrate, and including: a plurality of first electrodes arranged side by side, and two adjacent ones of the plurality of first electrodes is provided with a slit therebetween.

Optionally, each of the plurality of first electrodes includes: a plurality of first sub-electrodes and a plurality of second sub-electrodes connected in one-to-one correspondence, each first sub-electrode and each second sub-electrode extend to be connected to each other, points at which the plurality of first sub-electrodes are connected to the plurality of second sub-electrodes of each first electrode in one-to-one correspondence are located on the same straight line, and points at which the first sub-electrodes are connected to the second sub-electrodes of the first electrodes in the same row in one-to-one correspondence are located on the same straight line.

Optionally, each of the plurality of first electrodes further includes: a second electrode connected to the plurality of first sub-electrodes and a third electrode connected to the plurality of second sub-electrodes, and each thin film transistor further includes: a source electrode in the same layer as the drain electrode; in a sub-pixel, the second electrode is connected to the source electrode, and an orthographic projection of the third electrode on the substrate at least partially overlaps with an orthographic projection of the corresponding auxiliary touch line on the substrate; and in a sub-pixel, the second electrode is connected to the source electrode, and the orthographic projection of the third electrode on the substrate at least partially overlaps with an orthographic projection of the corresponding auxiliary data line on the substrate.

Optionally, each sub-pixel further includes: a common electrode, the common electrode is also used as a touch electrode, and a region where a touch electrode is located is a touch unit; and the common electrodes in each touch unit are connected to each other, the common electrodes of the two sub-pixels between every two adjacent main touch lines in the first direction form one repeating unit, and the common electrodes in two adjacent repeating units are connected to each other by a connection portion in the first direction or the second direction.

Optionally, the common electrode has a first opening; and an orthographic projection of the first opening on the substrate at least partially overlaps with an orthographic projection of the corresponding auxiliary data line on the substrate.

Optionally, the common electrode further has a second opening; and an orthographic projection of the second opening on the substrate at least partially overlaps with an orthographic projection of the corresponding main touch line on the substrate.

Optionally, the common electrode further has a third opening; and an orthographic projection of the third opening on the substrate at least partially overlaps with an orthographic projection of the corresponding auxiliary touch line on the substrate.

Optionally, the common electrode is located on a side of the pixel electrode away from the substrate, the common electrode of each sub-pixel includes: a plurality of fourth electrodes arranged side by side, adjacent ones of the plurality of fourth electrodes is provided with a slit therebetween, and the pixel electrode of each sub-pixel is a planar electrode.

Optionally, the pixel electrode has two opposite ends in the second direction; in a sub-pixel, one end of the pixel electrode is connected to the source electrode, and an orthographic projection of the other end of the pixel electrode on the substrate at least partially overlaps with an orthographic projection of the corresponding auxiliary data line on the substrate; and in a sub-pixel, one end of the pixel electrode is connected to the source electrode, and an orthographic projection of the other end of the pixel electrode on the substrate at least partially overlaps with an orthographic projection of the corresponding auxiliary touch line on the substrate.

In a second aspect, an embodiment of the present disclosure provides a touch display apparatus, including the above touch display substrate.

### BRIEF DESCRIPTION OF DRAWINGS

FIG. 1 is a schematic diagram of a structure of an exemplary touch display substrate.

FIG. 2a is a schematic diagram of a structure of a touch display substrate according to an embodiment of the present disclosure.

FIG. 2b is a simplified schematic diagram of a structure of the touch display substrate shown in FIG. 2a.

FIG. 3a is an enlarged schematic diagram of an M region of the touch display substrate in a dotted frame shown in FIG. 2a.

FIG. 3b is a schematic cross-sectional view of the structure shown in FIG. 3a along a direction A-A′.

FIG. 3c is a schematic cross-sectional view of the structure shown in FIG. 3a along a direction B-B′.

FIG. 3d is a schematic cross-sectional view of a routing structure implemented on the touch display substrate shown in FIG. 2a.

FIG. 4a is an enlarged schematic diagram of a thin film transistor in an N region of the touch display substrate in a dotted frame shown in FIG. 2a.

FIG. 4b is an enlarged schematic diagram of a thin film transistor in an N′ region of the touch display substrate in a dotted frame shown in FIG. 2a.

FIG. 5 is an enlarged schematic diagram of a P region of the touch display substrate in a dotted frame shown in FIG. 2a.

FIG. 6 is a schematic diagram of a structure of a common electrode in the touch display substrate shown in FIG. 2a.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

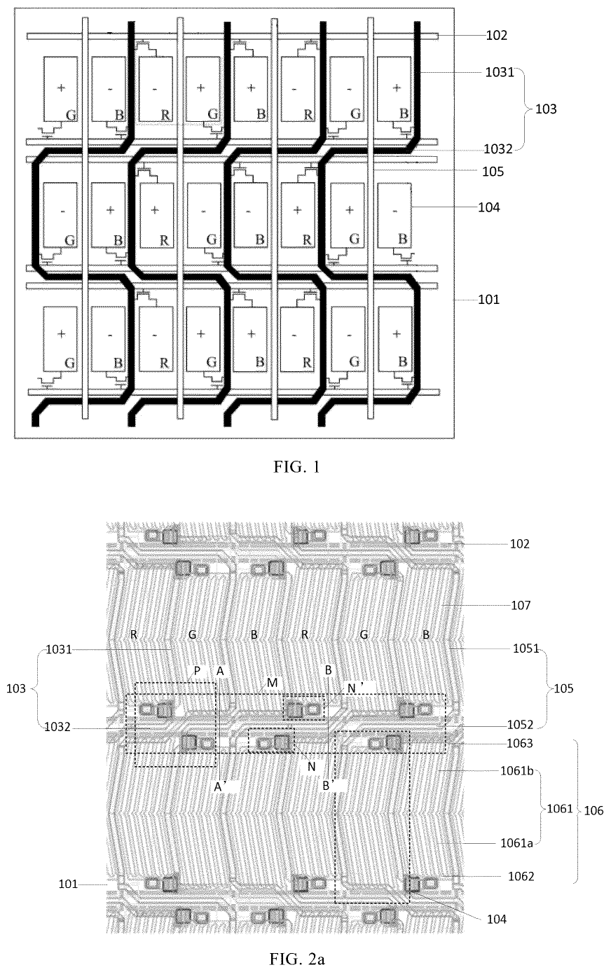

FIG. 1 is a schematic diagram of a structure of an exemplary touch display substrate. As shown in FIG. 1, the touch display substrate includes: a substrate 101, gate lines 102 and data lines 103 on the substrate 101, and a plurality of sub-pixels 104 in regions where the gate lines 102 and the data lines 103 cross each other. Two gate lines 102 are arranged between every two adjacent rows of sub-pixels 104, each gate line 102 extends in a first direction, and one data line 103 is arranged every two columns of sub-pixels 104. Each data line 103 includes: main data lines 1031 and auxiliary data lines 1032, the main data lines 1031 extend in a second direction, the auxiliary data lines 1032 extend in the first direction, and any two adjacent main data lines 1031 are connected by one auxiliary data line 1032. The first direction intersects with the second direction. For example, the first direction is a row direction, and the second direction is a column direction. The adjacent main data lines 1031 are located on different straight lines, and the main data lines 1031 separated from each other are located on the same straight line. Each of the auxiliary data lines 1032 spans at least two adjacent sub-pixels 104. For example, each data line 103 is routed in a circular manner where a first auxiliary data line 1032 extends towards the left in the row direction by a distance of two sub-pixels 104, a main data line 1031 close to an extending end of the first auxiliary data line 1032 extends downward by a distance of one sub-pixel 104, and a second auxiliary data line 1032 close to an extending end of the main data line 1031 extends towards the right in the row direction by a distance of two sub-pixels 104, and the same cycle is for the remaining main data lines 1031 and the remaining auxiliary data lines 1032.

With reference to FIG. 1, for the two gate lines 102 arranged between every two adjacent rows of sub-pixels 104, one of them is connected to half of the same row of the sub-pixels 104, and the other gate line 102 is connected to the other half of the same row of the sub-pixels 104. The touch display substrate further includes: touch lines 105 on the substrate 101 extending in the second direction, and one touch line 105 is located between every two adjacent main data lines 1031.

However, in a display process of the touch display substrate in the related art, vertical stripes of sky blue or other problems are easily caused due to the connection between the gate lines 102 and the sub-pixels 104. Further, each data line 103 adopts a bow-shaped routing structure (i.e., having a shape of a Chinese character “ [symbol] ”) formed by the main data lines 1031 and the auxiliary data lines 1032, each touch line 105 adopts a common linear routing structure, and the auxiliary data lines 1032 of each data line 103 extending in the first direction overlap with the corresponding touch line 105, so that an overlapping capacitor is easily generated therebetween, and the loads of the data lines 103 and the touch lines 105 are large, which adversely affects the energy consumption of the touch display substrate. In addition, the data lines 103 and the touch lines 105 are formed by using different masks, respectively, so that the number of the masks is increased, the preparation cost is increased, and the requirements of users on low cost and high performance cannot be met.

In order to solve at least one of the above technical problems, an embodiment of the present disclosure provides a touch display substrate and a touch display apparatus, which will be described in further detail with reference to the accompanying drawings and specific embodiments.

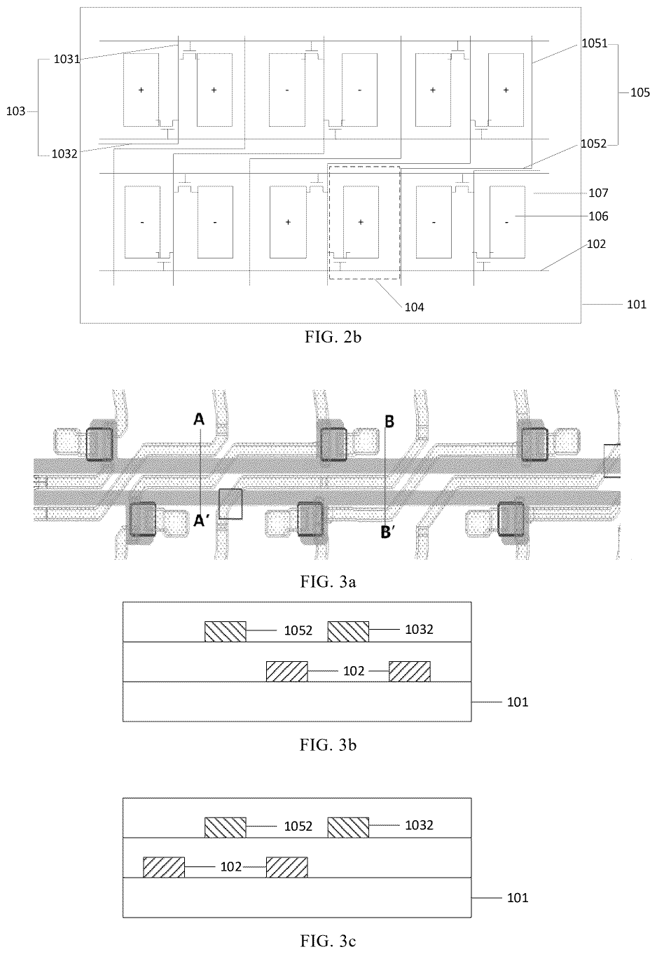

In a first aspect, an embodiment of the present disclosure provides a touch display substrate. FIG. 2a is a schematic diagram of a structure of a touch display substrate according to an embodiment of the present disclosure. FIG. 2b is a simplified schematic diagram of a structure of the touch display substrate shown in FIG. 2a. As shown in FIG. 2a and FIG. 2b, the touch display substrate includes: a substrate 101, gate lines 102 and data lines 103 on the substrate 101, and a plurality of sub-pixels 104 in regions where the gate lines 102 and the data lines 103 cross each other. Two gate lines 102 are arranged between every two adjacent rows of sub-pixels 104, each gate line 102 extends in a first direction, and each data line 103 includes: main data lines 1031 and auxiliary data lines 1032, the main data lines 1031 extend in a second direction, the auxiliary data lines 1032 extend in the first direction, any two adjacent main data lines 1031 of each data line 103 are connected by one auxiliary data line 1032 of the data line 103, and any two main data lines 1031 adjacent to each other in the first direction are separated from each other by two sub-pixels 104. The first direction intersects with the second direction. The adjacent main data lines 1031 of each data line 103 are located on different straight lines, and the main data lines 1031 separated from each other are located on the same straight line. Each of the auxiliary data lines 1032 spans at least two adjacent sub-pixels 104 in the first direction. The touch display substrate further includes: touch lines 105 on the substrate 101. Each touch line 105 includes: main touch lines 1051 and auxiliary touch lines 1052. The main touch lines 1051 extend along the second direction, the auxiliary touch lines 1052 extend along the first direction, and any two adjacent main touch lines 1051 of each touch line 105 are connected by one auxiliary touch line 1052 of the touch line 105. The adjacent main touch lines 1051 of each touch line 105 are located on different straight lines, and the main touch lines 1051 separated from each other are located on the same straight line. The main touch lines 1051 and the main data lines 1031 extending along the first direction are alternately arranged, and each auxiliary touch line 1052 and each auxiliary data line 1032 span the same number of the sub-pixels 104.

The substrate 101 may be made of a rigid material such as glass, which can improve the carrying capacity of the substrate 101 for other layers on the substrate 101. Alternatively, the substrate 101 may be made of a flexible material such as polyimide (PI), which can improve the overall bending and stretching resistance of the display substrate, and prevent the substrate 101 from being broken due to the stress generated when the display substrate is bent, stretched, and twisted, and therefore avoid the open circuit. In practical applications, the material of the substrate 101 may be selected reasonably according to actual needs to ensure that the display substrate has the good performances.

The gate lines 102 and the data lines 103 may be made of a metal material, such as one or an alloy of molybdenum (Mo), aluminum (Al) and titanium (Ti). The gate lines 102 and the data lines 103 may each have a single-layer structure or a multi-layer structure. In the embodiment of the present disclosure, as an example, the gate lines 102 and the data lines 103 each have the single-layer structure. Two gate lines 102 are arranged between every two adjacent rows of sub-pixels 104, and the gate lines 102 may extend in the row direction. Any two adjacent main data lines 1031 in the first direction are separated from each other by two sub-pixels. For example, each data line 103 is routed in a circular manner by taking 2×6 sub-pixels as a repeating unit where a first auxiliary data line 1032 extends towards the left in the row direction by a distance of two sub-pixels 104, a main data line 1031 close to an extending end of the first auxiliary data line 1032 extends downward by a distance of one sub-pixel 104, and a second auxiliary data line 1032 close to an extending end of the main data line 1031 extends towards the right in the row direction by a distance of two sub-pixels 104, and the same cycle is for the remaining main data lines 1031 and the remaining auxiliary data lines 1032. The adjacent main data lines 1031 are located on different straight lines, and the main data lines 1031 separated from each other are located on the same straight line. Each of the auxiliary data lines 1032 spans at least two adjacent sub-pixels 104 in the first direction. In this way, each data line 103 may have a bow-shaped routing structure.

In the display process, data signals with different polarities may be input into any two adjacent data lines 103. For example, a positive data signal is input into any one data line 103, and a negative data signal is input into the other data line 103 adjacent to the data line 103, so that the data signals with different polarities may be input into adjacent sub-pixels 104 in the same row connected to the two adjacent data lines 103. Because each data line 103 adopts a bow-shaped routing structure, the data signals with different polarities may be input into adjacent sub-pixels 104 in the same column connected to the data line 103. Therefore, the polarities of the voltages of the sub-pixels 104 having the same type (color) in the same frame of image are averaged (uniformly distributed) in space, and bright and dark stripes alternatively arranged are visually avoided, thereby improving the display effect.

The touch lines 105 may be made of a metal material, such as one or an alloy of molybdenum (Mo), aluminum (Al) and titanium (Ti). The gate lines 102 and the data lines 103 may each have a single-layer structure or a multi-layer structure. In the embodiment of the present disclosure, as an example, the touch lines 105 have the single-layer structure. Any two main touch lines 1051 adjacent to each other in the first direction are separated by two sub-pixels. For example, each touch line 105 is also routed in a circular manner by taking 2×6 sub-pixels as a repeating unit where a first auxiliary touch line 1052 extends towards the left in the row direction by a distance of two sub-pixels 104, a main touch line 1051 close to an extending end of the first auxiliary touch line 1052 extends downward by a distance of one sub-pixel 104, and a second auxiliary touch line 1052 close to an extending end of the main touch line 1051 extends towards the right in the row direction by a distance of two sub-pixels 104, and the same cycle is for the remaining main touch lines 1051 and the remaining auxiliary touch lines 1052. The adjacent main touch lines 1051 are located on different straight lines, and the main touch lines 1051 separated from each other are located on the same straight line. Each of the auxiliary touch lines 1052 spans at least two adjacent sub-pixels 104 in the first direction. In this way, each touch line 105 may have the same bow-shaped routing structure as the data line 103.

It should be noted that the adjacent main data lines 1031 are two main data lines 1031 sequentially connected by the same auxiliary data line 1032 in the same data line 103, the adjacent main touch lines 1051 are two main touch lines 1051 sequentially connected by the same auxiliary touch line 1052 in the same touch line 105, the main data lines 1031 separated from each other are two main data lines 1031 connected by different auxiliary data lines 1032 in the same data line 103, respectively, and the main touch lines 1051 separated from each other are two main touch lines 1051 connected by different auxiliary touch lines 1052 in the same touch line 105, respectively. In the embodiment of the present disclosure, since each data line 103 has bending portions, the main data lines 1031 separated from each other are located on the same straight line, which may means that odd-numbered main data lines 1031 of each data line 103 overlap with a first straight line along the second direction, and even-numbered main data lines 1031 of each data line 103 overlap with a second straight line along the second direction. Similarly, since each touch line 105 has bending portions, the main touch lines 1051 separated from each other are located on the same straight line, which may means that odd-numbered main touch lines 1051 of each touch line 105 overlap with a third straight line along the second direction, and even-numbered main touch lines 1051 of each touch line 105 overlap with a fourth straight line along the second direction. The first straight line does not overlap with the second straight line and the third straight line does not overlap with the fourth straight line.

In the touch display substrate provided by the embodiment of the present disclosure, the data lines 103 and the touch lines 105 both adopt the same bow-shaped routing structure, an orthographic projection of the data lines 103 on the substrate 101 does not overlap with an orthographic projection of the touch lines 105 on the substrate 101, and each auxiliary touch line 1052 and each auxiliary data line 1032 span the same number of the sub-pixels 104, so that the parasitic capacitance can be prevented from being generated between the data lines 103 and the touch lines 105, the load of the data lines 103 and the touch lines 105 can be therefore reduced, and the energy consumption of the touch display substrate is reduced, thereby meeting the user requirement on the low energy consumption and the high performance.

It should be noted that the number of the sub-pixels 104 spanned by each of the auxiliary data lines 1032 and the auxiliary touch lines 1052 may alternatively be 4, 6, or the like, and a specific length of each of the auxiliary data lines 1032 and the auxiliary touch lines 1052 may be set according to actual needs, which is not enumerated here.

In some embodiments, as shown in FIG. 2a, the sub-pixels 104 includes: first sub-pixels, second sub-pixels and third sub-pixels. For two adjacent gate lines 102 on opposite sides of each row of sub-pixels 104, one gate line 102 is connected to all first sub-pixels and half of third sub-pixels in the row, and the other gate line 102 is connected to all second sub-pixels and the other half of the third sub-pixels in the row.

Each first sub-pixel may be a red sub-pixel R, each second sub-pixel may be a green sub-pixel G, and each third sub-pixel may be a blue sub-pixel B. Since the data lines 103 adopt the bow-shaped routing structure, each data line 103 may charge (that is, provide signals to) at least four columns of sub-pixels 104, and different columns of sub-pixels 104 are controlled by the plurality of gate lines 102 to be charged independently. When each data line 103 charges the plurality of columns of sub-pixels 104, some adjacent sub-pixels 104 are easy to be insufficiently charged. In the embodiment of the present disclosure, half of the blue sub-pixels B in the same row are connected to one gate line 102, and the other half of the blue sub-pixels B are connected to the other gate line 102. When a mixed color display is performed on the blue sub-pixels B and the green sub-pixels G, insufficiently charged sub-pixels and pre-charged sub-pixels of the blue sub-pixels B and the green sub-pixels G may offset each other, so that the vertical stripes of sky blue can be avoided, and the display effect of the touch display substrate can be improved.

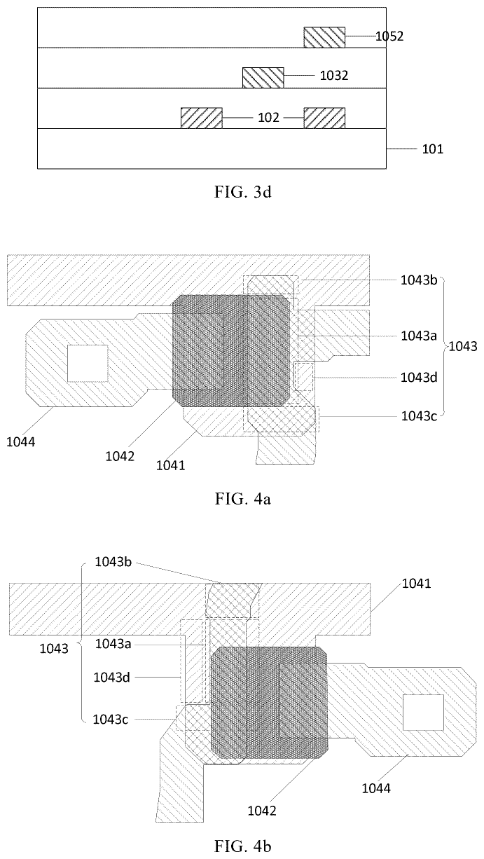

FIG. 3a is an enlarged schematic diagram of an M region of the touch display substrate in a dotted frame shown in FIG. 2a. FIG. 3b is a schematic cross-sectional view of the structure shown in FIG. 3a along a direction A-A′. FIG. 3c is a schematic cross-sectional view of the structure shown in FIG. 3a along a direction B-B′. As shown in FIG. 3a, FIG. 3b and FIG. 3c, the gate lines 102 are located on the substrate 101, and the data lines 103 and the touch lines 105 are disposed in the same layer and located on a side of the gate lines 102 away from the substrate 101.

Since the data lines 103 and the touch lines 105 adopt the same bow-shaped routing structure and the data lines 103 and the touch lines 105 do not overlap with each other, the data lines 103 and the touch lines 105 may be arranged in the same layer. That is, the data lines 103 and the touch lines 105 are made of the same material and are formed through the same process, so that the number of masks can be reduced, the process steps can be reduced, and the manufacturing cost can be saved. Specifically, an orthographic projection of the auxiliary data lines 1032 extending along the second direction on the substrate 101 and an orthographic projection of the auxiliary touch lines 1052 extending along the second direction on the substrate 101 are located on opposite sides of an orthographic projection of a corresponding gate line 102 on the substrate 101, respectively.

For example, as shown in FIG. 3b, each auxiliary data line 1032 is located between the two adjacent gate lines 102, each auxiliary touch line 1052 and each auxiliary data line 1032 are disposed in the same layer, a gate insulating layer is disposed between a layer where the gate lines 102 are located and a layer where the auxiliary data line 1032 and the auxiliary touch line 1052 are located, and a planarization layer covers the auxiliary data line 1032 and the auxiliary touch line 1052 to prevent short circuit between adjacent conductive layers.

For example, as shown in FIG. 3c, each auxiliary touch line 1052 is located between the two adjacent gate lines 102, each auxiliary data line 1032 and each auxiliary touch line 1052 are disposed in the same layer, a gate insulating layer is disposed between a layer where the gate lines 102 are located and a layer where the auxiliary data line 1032 and the auxiliary touch line 1052 are located, and a planarization layer covers the auxiliary data line 1032 and the auxiliary touch line 1052 to prevent short circuit between adjacent conductive layers.

In practical applications, a distance between an orthographic projection of each of the auxiliary data lines 1032 and the auxiliary touch lines 1052 on the substrate 101 and an orthographic projection of the corresponding gate line 102 on the substrate 101 is greater than or equal to 1 micrometer and less than or equal to 3.5 micrometers. That is, the distance between the two adjacent lines (the auxiliary data line 1032 and the corresponding gate line 102 or the auxiliary touch line 1052 and the corresponding gate line 102) is greater than or equal to 1 micrometer and less than or equal to 3.5 micrometers, so that a short circuit between the two adjacent lines can be prevented, and the mutual interference between the two adjacent lines is avoided, and therefore the touch display effect is prevented from being adversely affected. For example, the distance between the auxiliary data line 1032 and the corresponding gate line 102 is 2 micrometers, and the distance between the gate line 102 and the corresponding auxiliary touch line 1052 is 2 micrometers. It can be understood that the distance between the two adjacent lines may alternatively be other value, which may be set according to actual needs, and is not enumerated here.

FIG. 3d is a schematic cross-sectional view of a routing structure implemented on the touch display substrate shown in FIG. 2a. As shown in FIG. 3d, the gate lines 102 are located on the substrate 101, the data lines 103 are located on a side of the gate lines 102 away from the substrate 101, and the touch lines 105 are located on a side of the data lines 103 away from the substrate 101.

The gate lines 102 are located on the substrate 101, the data lines 103 are located on a side of the gate lines 102 away from the substrate 101, and the touch lines 105 are located on a side of the data lines 103 away from the substrate 101, so that the data lines 103 and the touch lines 105 may be located in different conductive layers. Since there are the great number of insulating layers between a layer where the touch lines 105 are located and a layer where the gate lines 102 are located, which can achieve a good insulating effect, it may unnecessarily consider a routing distance between each touch line 105 and the corresponding gate line 102, and a routing space can be reduced.

Specifically, an orthographic projection of each auxiliary data line 1032 on the substrate 101 is between orthographic projections of two gate lines 102 between two rows of sub-pixels 104 adjacent to the auxiliary data line 1032 on the substrate 101, and an orthographic projection of each auxiliary touch line 1052 on the substrate 101 overlaps with an orthographic projection of one corresponding gate line 102 on the substrate 101.

Since the gate lines 102, the auxiliary data lines 1032 and the auxiliary touch lines 1052 are all located in different layers, the orthographic projection of each auxiliary touch line 1052 on the substrate 101 coincides with the orthographic projection of one corresponding gate line 102 on the substrate 101, so that the routing space is reduced, a pixel aperture ratio of the touch display substrate is increased, and the display effect is improved.

The distance between the orthographic projection of each auxiliary data line 1032 on the substrate 101 and the orthographic projection of each of the two gate lines 102 between the two rows of sub-pixels 104 adjacent to the auxiliary data line 1032 on the substrate 101 is greater than or equal to 1 micrometer and less than or equal to 3.5 micrometers, and the distance between the orthographic projection of each auxiliary data line 1032 on the substrate 101 and the orthographic projection of the corresponding auxiliary touch line 1052 on the substrate 101 is greater than or equal to 1 micrometer and less than or equal to 3.5 micrometers.

In practical applications, the distance between the orthographic projection of each auxiliary data line 1032 on the substrate 101 and the orthographic projection of each of the two gate lines 102 between the two rows of sub-pixels 104 adjacent to the auxiliary data line 1032 on the substrate 101 is greater than or equal to 1 micrometer and less than or equal to 3.5 micrometers, and the distance between the orthographic projection of each auxiliary data line 1032 on the substrate 101 and the orthographic projection of the corresponding auxiliary touch line 1052 on the substrate 101 is greater than or equal to 1 micrometer and less than or equal to 3.5 micrometers. That is, the distance between the two adjacent lines (the auxiliary data line 1032 and the corresponding gate line 102 or the auxiliary data line 1032 and the corresponding auxiliary touch line 1052) is greater than or equal to 1 micrometer and less than or equal to 3.5 micrometers, so that a short circuit between the two adjacent lines can be prevented, and the mutual interference between the two adjacent lines is avoided, and therefore the touch display effect is prevented from being adversely affected. For example, the distance between the auxiliary data line 1032 and the corresponding gate line 102 is 2 micrometers, and the distance between the auxiliary data line 1032 and the corresponding auxiliary touch line 1052 is 2 micrometers. It can be understood that the distance between the two adjacent lines may alternatively be other value, which may be set according to actual needs, and is not enumerated here.

FIG. 4 a is an enlarged schematic diagram of a thin film transistor in an N region of the touch display substrate in a dotted frame shown in FIG. 2a. FIG. 4b is an enlarged schematic diagram of a thin film transistor in an N′ region of the touch display substrate in a dotted frame shown in FIG. 2a. As shown in FIG. 4a and FIG. 4b, each sub-pixel 104 includes: a thin film transistor, including: a gate electrode 1041, a semiconductor layer 1042 and a drain electrode 1043 sequentially arranged along a direction away from the substrate 101, the gate electrode 1041 is connected to the corresponding gate line 102, and the drain electrode 1043 is connected to the corresponding data line 102. The drain electrode 1043 includes: a main portion 1043a and a first extension portion 1043b located on a side of the main portion 1043a close to the corresponding gate line 102. An orthographic projection of the main portion 1043a on the substrate 101 covers a portion of an orthographic projection of the semiconductor layer 1042 on the substrate 101, and an orthographic projection of the first extension portion 1043b on the substrate 101 does not overlap with the orthographic projection of the semiconductor layer 1042 on the substrate 101.

The gate electrode 1041 of the thin film transistor may be connected to the corresponding gate line 102, the gate line 102 may transmit a scan signal to the gate electrode 1041, and the semiconductor layer 1042 may be turned on by the scan signal. The drain electrode 1043 may be connected to the corresponding data line 103, and the data line 103 may transmit a data signal to the drain electrode 1043. The drain electrode 1043 is also connected to one end of the semiconductor layer 1042 to transmit the data signal through the semiconductor layer 1042. A material of the semiconductor layer 1042 may be a metal oxide, such as indium gallium zinc oxide (IGZO).

The main portion 1043a of the drain electrode 1043 may cover a portion of the semiconductor layer 1042, and may overlap with (and be connected to) one end of the semiconductor layer 1042, and the first extension portion 1043b is connected to the main portion 1043a. For example, the first extension portion 1043b and the main portion 1043a may have a one-piece structure, the orthographic projection of the first extension portion 1043b on the substrate 101 does not overlap with the orthographic projection of the semiconductor layer 1042 on the substrate 101, and a boundary where the main portion 1043a is connected to the first extension portion 1043b is flush with an edge of the semiconductor layer 1042. In the process for manufacturing the touch display substrate, the drain electrode 1043 is likely to be shifted due to the requirement of alignment precision. When the drain electrode 1043 is shifted toward a direction away from the corresponding gate line 102, a reserved portion of the drain electrode 1043 exceeding the semiconductor layer 1042 on a side where the first extension portion 1043b is located can still cover the semiconductor layer 1042, so that an on-state current of the semiconductor layer 1042, a channel width of the thin film transistor and the uniformity among different thin film transistors are ensured, and the display effect of the touch display substrate is improved. Specifically, a width of the first extension portion 1043b in the first direction (the row direction) is greater than or equal to 2 micrometers and less than or equal to 10 micrometers, and a width of the first extension portion 1043b in the second direction (the column direction) is greater than or equal to 1.5 micrometers and less than or equal to 10 micrometers.

It is to be understood that the above thin film transistor is a bottom gate thin film transistor. The thin film transistor may alternatively be a top gate thin film transistor. For example, the thin film transistor includes: a semiconductor layer 1042, a gate electrode 1041 and a drain electrode 1043 sequentially arranged along a direction away from the substrate 101, the gate electrode 1041 is connected to the corresponding gate line 102, and the drain electrode 1043 is connected to the corresponding data line 102. The material of the semiconductor layer 1042 may be low temperature poly-silicon (LTPS), and an implementation principle of the top gate thin film transistor is similar to that of the bottom gate thin film transistor, and is not described herein again.

In some embodiments, as shown in FIGS. 4a and 4b, the drain electrode 1043 further includes: a second extension portion 1043c located on a side of the main portion 1043a away from the corresponding gate line 102 and connected to the main portion 1043a. For example, the second extension portion 1043c and the main portion 1043a may have a one-piece structure, and an orthographic projection of the second extension portion 1043c on the substrate 101 does not overlap with the orthographic projection of the semiconductor layer 1042 on the substrate 101.

A boundary where the main portion 1043a is connected to the second extension portion 1043c is flush with an edge of the semiconductor layer 1042. In the process for manufacturing the touch display substrate, the drain electrode 1043 is likely to be shifted due to the requirement of alignment precision. When the drain electrode 1043 is shifted toward a direction close to the corresponding gate line 102, a reserved portion of the drain electrode 1043 exceeding the semiconductor layer 1042 on a side where the second extension portion 1043c is located can still cover the semiconductor layer 1042, so that an on-state current of the semiconductor layer 1042, a channel width of the thin film transistor and the uniformity among different thin film transistors are ensured, and the display effect of the touch display substrate is improved. Specifically, a width of the second extension portion 1043c in the first direction (the row direction) is greater than or equal to 2 micrometers and less than or equal to 10 micrometers, and a width of the second extension portion 1043c in the second direction (the column direction) is greater than or equal to 1.5 micrometers and less than or equal to 10 micrometers.

In some embodiments, as shown in FIGS. 4a and 4b, the drain electrode 1043 further includes: a recessed portion 1043d located on a side of the main portion 1043a close to the corresponding data line 103, and an orthographic projection of the recessed portion 1043d on the substrate 101 falls within an orthographic projection of the gate electrode 1041 on the substrate 101.

A side of the main portion 1043a of the drain electrode 1043 is a straight line, and the second extension portion 1043c is connected to the main portion 1043a. The width of the second extension portion 1043c in the first direction is greater than a width of the main portion 1043a in the first direction. Edges of the main portion 1043a, the second extension portion 1043 c and the corresponding auxiliary data line 1032 may form the recessed portion 1043d in a surrounding manner (surround a space among them to form the recessed portion 1043d) (as shown in FIG. 4a), or edges of the main portion 1043a, the second extension portion 1043c and the corresponding main data line 1031 may form the recessed portion 1043d in a surrounding manner (as shown in FIG. 4b). A portion of the gate electrode 1041 may be exposed by the recessed portion 1043d, so that an overlapping area and the parasitic capacitance between the drain electrode 1043 and the gate electrode 1041 can be effectively reduced. In this way, the load of the whole touch display substrate can be reduced, a charging rate of the thin film transistor is advantageously improved and the power consumption of the touch display substrate is reduced. Specifically, a width of the recessed portion 1043d in the first direction (the row direction) is greater than or equal to 2 micrometers and less than or equal to 10 micrometers, and a width of the recessed portion 1043d in the second direction (the column direction) is greater than or equal to 2 micrometers and less than or equal to 10 micrometers.

In some embodiments, as shown in FIG. 2a, each sub-pixel 104 further includes: a pixel electrode 106 located on a side of the drain electrode 1043 away from the substrate 101, including: a plurality of first electrodes 1061 arranged side by side. A slit is provided between adjacent first electrodes 1061.

Each pixel electrode 106 is formed by the plurality of first electrodes 1061 arranged side by side, and the slit is formed between the adjacent first electrodes 1061, so that an electric field generated by an in-plane slit electrode and an electric field generated between plane electrodes form a multi-dimensional electric field, which rotates liquid crystal molecules, thereby improving the operation efficiency of the liquid crystal molecules, and increasing the light transmission efficiency.

In some embodiments, as shown in FIG. 2a, each first electrode 1061 includes: a plurality of first sub-electrodes 1061a and a plurality of second sub-electrodes 1061b connected in one-to-one correspondence. Extending directions of each first sub-electrode 1061a and each second sub-electrode 1061b intersect with each other. In some embodiments, points at which the first sub-electrodes 1061a are connected to the second sub-electrodes 1061b of each first electrode 1061 in one-to-one correspondence are located on the same straight line. In some embodiments, points at which the first sub-electrodes 1061a are connected to the second sub-electrodes 1061b of the first electrodes 1061 in the same row in one-to-one correspondence are located on the same straight line.

In each pixel electrode 106, the extending directions of the first sub-electrodes 1061a and the second sub-electrodes 1061b are located on different straight lines, so that a multi-domain state of the liquid crystals can be realized. The points at which the first sub-electrodes 1061a are connected to the second sub-electrodes 1061b of each first electrode 1061 in one-to-one correspondence are located on the same straight line and the points at which the first sub-electrodes 1061a are connected to the second sub-electrodes 1061b of the first electrodes 1061 in the same row in one-to-one correspondence are located on the same straight line, which is beneficial to close arrangement of the electrodes, and can ensure that rotation directions of the liquid crystal molecules are consistent, thereby improving the display effect of the touch display substrate. The first sub-electrodes 1061a and the second sub-electrodes 1061b in are alternately arranged (each column of sub-pixels 104 have the same structure). Each row of sub-pixels 104 may be divided into an upper half part and a lower half part by taking a straight line passing through the points at which the first sub-electrodes 1061a are connected to the second sub-electrodes 1061b in one-to-one correspondence as a boundary. The number of the first sub-electrodes 1061a in the upper half part of each row of sub-pixels 104 and the number of the second sub-electrodes 1061b in the lower half part of each row of sub-pixels 104 are the same.

In some embodiments, as shown in FIG. 2a, each pixel electrode 106 further includes: a second electrode 1062 connected to the first sub-electrodes 1061a and a third electrode 1063 connected to the second sub-electrodes 1061b, each thin film transistor further includes: a source electrode 1044 in the same layer as the drain electrode 1043, and in each pixel electrode 106, the third electrode 1063 is farther away from the source electrode 1044 than the second electrode 1062.

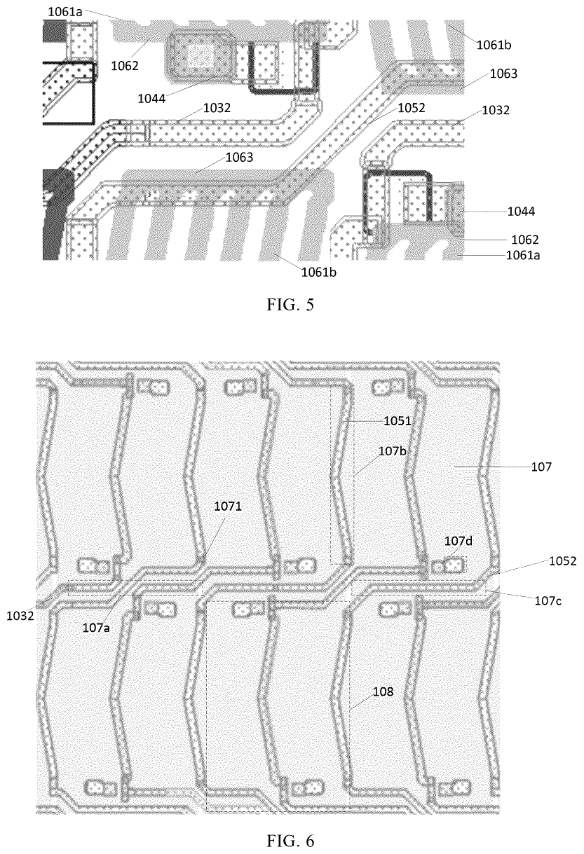

FIG. 5 is an enlarged schematic diagram of a P region of the touch display substrate in a dotted frame shown in FIG. 2a. As shown in FIG. 5, in a sub-pixel 104, the second electrode 1062 is connected to the source electrode 1044, and an orthographic projection of the third electrode 1063 on the substrate 101 at least partially overlaps with an orthographic projection of the corresponding auxiliary data line 1032 on the substrate 101. In some embodiments, in a sub-pixel 104, the second electrode 1062 is connected to the source electrode 1044, and the orthographic projection of the third electrode 1063 on the substrate 101 at least partially overlaps with an orthographic projection of the corresponding auxiliary touch line 1052 on the substrate 101.

In a sub-pixel 104, the second electrode 1062 may be disposed at an upper position in the sub-pixel 104, and is connected to the source electrode 1044 and the first sub-electrodes 1061a, so that the first sub-electrodes 1061a are close to the source electrode 1044, and a length of each first sub-electrode 1061a is less than that of each second sub-electrode 1061b, so as to prevent the thin film transistor from shielding the second electrode 1062, thereby increasing an aperture ratio of the sub-pixel 104. In addition, an edge of the third electrode 1063 may exceed an edge of the corresponding auxiliary data line 1032 or the corresponding auxiliary touch line 1052. Since the auxiliary data line 1032, the auxiliary touch line 1052 and the second electrode 1062 all have a light-shielding function, the third electrode 1063 may overlap with the corresponding auxiliary data line 1032 or the corresponding auxiliary touch line 1052 to increase the aperture ratio of the sub-pixel 104, thereby increasing the light transmittance of the entire touch display substrate and reducing the power consumption of the touch display substrate. In a sub-pixel 104, the second electrode 1062 may be disposed at a lower position in the whole sub-pixel 104, which has the same as the above principle of the case where the second electrode 1062 is disposed at the upper position in the whole sub-pixel 104 in the sub-pixel 104, and the detailed description thereof is omitted here.

FIG. 6 is a schematic diagram of a structure of a common electrode in the touch display substrate shown in FIG. 2a. As shown in FIG. 6, each sub-pixel 104 further includes: a common electrode 107, the common electrode 107 is also used as a touch electrode, and a region where respective touch electrodes are located is a touch unit. The common electrodes 107 in each touch unit are connected to each other, and the common electrodes 107 of the two sub-pixels 104 between every two adjacent main touch lines 1051 in the first direction form one repeating unit 108. The common electrodes in the adjacent repeating units 108 are connected to each other by a connection portion 1071 in the first direction or the second direction.

The common electrodes 107 may be located on a side of the pixel electrode 106 close to the substrate 101, the two sub-pixels 104 are disposed between every two adjacent main touch lines 1051 in the first direction, and the common electrodes 107 of the two sub-pixels 104 are connected together, and may have a one-piece structure. That is, the common electrodes 107 of the two sub-pixels 104 are formed by using the same material through the same preparation process. The common electrodes 107 of the two sub-pixels 104 disposed between every two adjacent main touch lines 1051 in the first direction forms a repeating unit 108, and in each touch unit, the repeating units 108 are connected together by the connection portions 1071, and the adjacent repeating units in the first direction or the second direction are connected to each other by the connection portions 1071. Adjacent repeating units 108 in adjacent touch units are disconnected from each other to obtain a plurality of touch units arranged in an array.

The common electrode 107 of each sub-pixel 104 is formed by a planar electrode, a common signal may be input into the common electrode 107 to form an electric field between the common electrode 107 and the pixel electrode 106, so as to drive the liquid crystal molecules to rotate, thereby realizing a display function. The touch display substrate is further divided into the plurality of touch units, each provided with one touch electrode, and the common electrodes 107 of the sub-pixels 104 may be formed through a single patterning process in the preparation process, so that the process steps are reduced, and the preparation cost is saved. In some embodiments, the common electrodes 107 of the sub-pixels 104 and the connection portions 1071 may be formed through a single patterning process in the preparation process.

In some embodiments, the common electrodes 107 may be located on a side of the pixel electrode 106 away from the substrate 101.

As shown in FIG. 6, the common electrode 107 has a first opening 107a. An orthographic projection of the first opening 107a on the substrate 101 at least partially overlaps with an orthographic projection of each of the corresponding auxiliary data lines 1032 on the substrate 101 and crosses an orthographic projection of the corresponding auxiliary touch line 1052 on the substrate 101, and connection portions 1071 of two adjacent repeating units 108 in the second direction are provided at both ends of the first opening 107a.

The first opening 107a may expose a part of each of the corresponding auxiliary data lines 1032, so that an overlapping area between the common electrode 107 and the auxiliary data line 1032 can be effectively reduced, and a parasitic capacitance between the common electrode 107 and the auxiliary data line 1032 can be reduced, thereby reducing the load of the whole touch display substrate, advantageously improving the charging rate of the thin film transistor and reducing the power consumption of the touch display substrate. A width of the first opening 107a may be in a range from 3 um to 10 um, and a length of the first opening 107a may be specifically determined according to a size of each sub-pixel 104, and is typically in a range from 6 um to 50 um.

As shown in FIG. 6, the common electrode 107 further has a second opening 107b. An orthographic projection of the second opening 107b on the substrate 101 at least partially overlaps with an orthographic projection of the corresponding main touch line 1051 on the substrate 101, and connection portions 1071 of two adjacent repeating units 108 in the first direction are provided at both ends of the second opening 107b. In some embodiments, the orthographic projection of the second opening 107b on the substrate 101 and the orthographic projection of the corresponding main touch line 1051 on the substrate 101 have a second overlapping region, and a length of the second overlapping region along the second direction is equal to that of the corresponding main touch line 1051 in the second overlapping region.

The second opening 107b may expose a part of the corresponding main touch line 1051, so that an overlapping area between the common electrode 107 and the main touch line 1051 can be effectively reduced, and a parasitic capacitance between the common electrode 107 and the main touch line 1051 can be reduced, thereby reducing the load of the whole touch display substrate, advantageously improving the charging rate of the thin film transistor and reducing the power consumption of the touch display substrate.

As shown in FIG. 6, the common electrode 107 further has a third opening 107c. An orthographic projection of the third opening 107c on the substrate 101 at least partially overlaps with an orthographic projection of the corresponding auxiliary touch line 1052 on the substrate 101, and connection portions 1071 of two adjacent repeating units 108 in the second direction are provided at both ends of the third opening 107c. In some embodiments, the orthographic projection of the third opening 107c on the substrate 101 and the orthographic projection of the corresponding auxiliary touch line 1052 on the substrate 101 have a third overlapping region, and a length of the third overlapping region along the first direction is equal to that of the corresponding auxiliary touch line 1052 in the third overlapping region.

The third opening 107c may expose a part of the corresponding auxiliary touch line 1052, so that an overlapping area between the common electrode 107 and the auxiliary touch line 1052 can be effectively reduced, and a parasitic capacitance between the common electrode 107 and the auxiliary touch line 1052 can be reduced, thereby reducing the load of the whole touch display substrate, advantageously improving the charging rate of the thin film transistor and reducing the power consumption of the touch display substrate.

It should be noted that the common electrode 107 is located on a side of the pixel electrode 106 close to the substrate 101, so that when the pixel electrode 106 is connected to the source electrode 1044 of the thin film transistor through a via, the via necessarily penetrates through the common electrode 107. Therefore, an avoiding opening 107d is necessarily disposed in the common electrode 107 to avoid the short circuit between the common electrode 107 and the pixel electrode 106, and therefore prevent the touch display effect from being affected.

In some embodiments, the common electrode 107 is located on a side of the pixel electrode 106 away from the substrate 101, the common electrode 107 of each sub-pixel 104 includes: a plurality of fourth electrodes (not shown) arranged side by side, a slit is provided between adjacent fourth electrodes, and the pixel electrode 106 of each sub-pixel 104 is a planar electrode.

The common electrode 107 may be located on a side of the pixel electrode 106 away from the substrate 101, and the arrangement of the common electrode 107 and the pixel electrode 106 is opposite to that in FIG. 2a, that is, the pixel electrode 106 is a planar electrode, and the common electrode 107 is a slit electrode. The implementation of such the case is the same as that in FIG. 2a, and will not be described in detail here.

In some embodiments, the pixel electrode 106 has two opposite ends in the second direction. In a sub-pixel 104, one end of the pixel electrode 106 is connected to the source electrode 1044, and an orthographic projection of the other end of the pixel electrode 106 on the substrate 101 at least partially overlaps with an orthographic projection of the corresponding auxiliary data line 1032 on the substrate 101. In a sub-pixel 104, one end of the pixel electrode 106 is connected to the source electrode 1044, and the orthographic projection of the other end of the pixel electrode 106 on the substrate 101 at least partially overlaps with an orthographic projection of the corresponding auxiliary touch line 1052 on the substrate 101.

In a sub-pixel 104, one end of the pixel electrode 106 may be disposed at an upper position in the sub-pixel 104, and is connected to the source electrode 1044, so as to prevent the thin film transistor from shielding the one end of the pixel electrode 106, thereby increasing an aperture ratio of the sub-pixel 104. In addition, an edge of the other end of the pixel electrode 106 may exceed an edge of the corresponding auxiliary data line 1032 or the corresponding auxiliary touch line 1052. Since the auxiliary data line 1032, the auxiliary touch line 1052 and the other end of the pixel electrode 106 all have a light-shielding function, the other end of the pixel electrode 106 may overlap with the corresponding auxiliary data line 1032 or the corresponding auxiliary touch line 1052 to increase the aperture ratio of the sub-pixel 104, thereby increasing the light transmittance of the entire touch display substrate and reducing the power consumption of the touch display substrate. In a sub-pixel 104, one end of the pixel electrode 106 may be disposed at a lower position in the whole sub-pixel 104, which has the same as the above principle of the case where one end of the pixel electrode 106 is disposed at the upper position in the whole sub-pixel 104 in the sub-pixel 104, and the detailed description thereof is omitted here.

In a second aspect, an embodiment of the present disclosure provides a touch display apparatus, including the touch display substrate provided in any one of the above embodiments. The touch display apparatus may be any product or component with a touch display function, such as a television, a mobile phone, a display, a notebook computer, a digital photo frame, or a navigator or the like. An implementation principle of the touch display substrate is similar to that of the touch display substrate, and is not described herein again.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A touch display substrate, comprising: a substrate, gate lines and data lines on the substrate, and a plurality of sub-pixels in regions where the gate lines and the data lines cross each other;
wherein two of the gate lines are arranged between every two adjacent rows of sub-pixels, the gate lines extend in a first direction, and each of the data lines comprises: main data lines and auxiliary data lines, the main data lines extend in a second direction, the auxiliary data lines extend in the first direction, any two adjacent main data lines of each of the data lines are connected by one auxiliary data line of the data line, and any two main data lines adjacent to each other in the first direction are separated from each other by two sub-pixels; the first direction intersects with the second direction; the adjacent main data lines of each data line are located on different straight lines, and the main data lines separated from each other are located on a same straight line; and each of the auxiliary data lines spans at least two adjacent sub-pixels in the first direction;
the touch display substrate further comprises: touch lines on the substrate, each of the touch lines comprises: main touch lines and auxiliary touch lines, the main touch lines extend along the second direction, the auxiliary touch lines extend along the first direction, any two adjacent main touch lines of each of the touch lines are connected by one auxiliary touch line of the touch line, the adjacent main touch lines of each of the touch lines are located on different straight lines, and the main touch lines separated from each other are located on a same straight line; and
the main touch lines and the main data lines extending along the first direction are alternately arranged, and each of the auxiliary touch lines and each of the auxiliary data lines span a same number of the sub-pixels in the first direction.

2. The touch display substrate of claim 1, wherein the plurality of sub-pixels comprise: first sub-pixels, second sub-pixels and third sub-pixels; and for two adjacent gate lines on two opposite sides of each row of sub-pixels, one gate line is connected to all first sub-pixels and one half of third sub-pixels in the row, and the other gate line is connected to all second sub-pixels and the other half of the third sub-pixels in the row.

3. The touch display substrate of claim 1, wherein the gate lines are on the substrate, and the data lines and the touch lines are arranged in a same layer and are on a side of the gate lines away from the substrate.

4. The touch display substrate of claim 3, wherein an orthographic projection of the auxiliary data line extending along the second direction on the substrate and an orthographic projection of the auxiliary touch line extending along the second direction on the substrate are located on two opposite sides of an orthographic projection of a corresponding gate line on the substrate, respectively.

5. The touch display substrate of claim 1, wherein the gate lines are on the substrate, the data lines are on a side of the gate lines away from the substrate, and the touch lines are on a side of the data lines away from the substrate.

6. The touch display substrate of claim 5, wherein an orthographic projection of each of the auxiliary data lines on the substrate is between orthographic projections of two gate lines adjacent to the auxiliary data line on the substrate, and the orthographic projection of each of the auxiliary touch lines on the substrate overlaps with the orthographic projection of one corresponding gate line on the substrate.

7. The touch display substrate of claim 1, wherein each sub-pixel comprises: a thin film transistor, comprising: a gate electrode, a semiconductor layer and a drain electrode sequentially arranged along a direction away from the substrate, the gate electrode is connected to the corresponding gate line, and the drain electrode is connected to the corresponding data line; the drain electrode comprises: a main portion and a first extension portion on a side of the main portion close to the corresponding gate line; and
an orthographic projection of the main portion on the substrate covers a portion of an orthographic projection of the semiconductor layer on the substrate, and an orthographic projection of the first extension portion on the substrate does not overlap with the orthographic projection of the semiconductor layer on the substrate.

8. The touch display substrate of claim 1, wherein each sub-pixel comprises: a thin film transistor, comprising: a semiconductor layer, a gate electrode, and a drain electrode sequentially arranged along a direction away from the substrate, the gate electrode is connected to the corresponding gate line, and the drain electrode is connected to the corresponding data line.

9. The touch display substrate of claim 7, wherein the drain electrode further comprises: a second extension portion on a side of the main portion away from the corresponding gate line; and
an orthographic projection of the second extension portion on the substrate does not overlap with an orthographic projection of the semiconductor layer on the substrate.

10. The touch display substrate of claim 9, wherein the drain electrode further comprises: a recessed portion on a side of the main portion close to the corresponding data line; and
an orthographic projection of the recessed portion on the substrate falls within an orthographic projection of the gate electrode on the substrate.

11. The touch display substrate of claim 7, wherein each sub-pixel further comprises: a pixel electrode on a side of the drain electrode away from the substrate, and comprising: a plurality of first electrodes arranged side by side, and two adjacent ones of the plurality of first electrodes is provided with a slit therebetween.

12. The touch display substrate of claim 11, wherein each of the plurality of first electrodes comprises: a plurality of first sub-electrodes and a plurality of second sub-electrodes connected in one-to-one correspondence, each first sub-electrode and each second sub-electrode extend to be connected to each other, points at which the plurality of first sub-electrodes are connected to the plurality of second sub-electrodes of each first electrode in one-to-one correspondence are located on a same straight line, and points at which the first sub-electrodes are connected to the second sub-electrodes of the first electrodes in a same row in one-to-one correspondence are located on a same straight line.

13. The touch display substrate of claim 12, wherein each of the plurality of first electrodes further comprises: a second electrode connected to the plurality of first sub-electrodes and a third electrode connected to the plurality of second sub-electrodes, and each thin film transistor further comprises: a source electrode arranged in a same layer as the drain electrode;
in each of some of the plurality of sub-pixels, the second electrode is connected to the source electrode, and an orthographic projection of the third electrode on the substrate at least partially overlaps with an orthographic projection of the corresponding auxiliary touch line on the substrate; and
in each of some of the plurality of sub-pixels, the second electrode is connected to the source electrode, and the orthographic projection of the third electrode on the substrate at least partially overlaps with an orthographic projection of the corresponding auxiliary data line on the substrate.

14. The touch display substrate of claim 7, wherein each sub-pixel further comprises a common electrode, which also functions as a touch electrode, and a region where each touch electrode is located belongs to a touch unit; and
the common electrodes in each touch unit are connected to each other, the common electrodes of the two sub-pixels between every two adjacent main touch lines in the first direction form one repeating unit, and the common electrodes in two adjacent repeating units are connected to each other by a connection portion in the first direction or the second direction.

15. The touch display substrate of claim 14, wherein the common electrode has a first opening; and
an orthographic projection of the first opening on the substrate at least partially overlaps with an orthographic projection of the corresponding auxiliary data line on the substrate.

16. The touch display substrate of claim 14, wherein the common electrode further has a second opening; and
an orthographic projection of the second opening on the substrate at least partially overlaps with an orthographic projection of the corresponding main touch line on the substrate.

17. The touch display substrate of claim 14, wherein the common electrode further has a third opening; and
an orthographic projection of the third opening on the substrate at least partially overlaps with an orthographic projection of the corresponding auxiliary touch line on the substrate.

18. The touch display substrate of claim 14, wherein the common electrode is located on a side of the pixel electrode away from the substrate, the common electrode of each sub-pixel comprises: a plurality of fourth electrodes arranged side by side, two adjacent fourth electrodes of the plurality of fourth electrodes is provided with a slit therebetween, and the pixel electrode of each sub-pixel is a planar electrode.

19. The touch display substrate of claim 18, wherein the pixel electrode has two opposite ends in the second direction;
in each of some of the plurality of sub-pixels, one end of the pixel electrode is connected to the source electrode, and an orthographic projection of the other end of the pixel electrode on the substrate at least partially overlaps with an orthographic projection of the corresponding auxiliary data line on the substrate; and
in each of some of the plurality of sub-pixels, one end of the pixel electrode is connected to the source electrode, and an orthographic projection of the other end of the pixel electrode on the substrate at least partially overlaps with an orthographic projection of the corresponding auxiliary touch line on the substrate.

20. A touch display apparatus, comprising the touch display substrate of claim 1.
